(19) United States
(12) Patent Application Publication
(10) Pub. No.: US 2025/0176335 A1
(43) Pub. Date: May 29, 2025

(54) DISPLAY DEVICE AND LIQUID CRYSTAL DISPLAY DEVICE

(71) Applicant: LG ELECTRONICS INC., Seoul (KR)

(72) Inventor: Taejoon SON, Seoul (KR)

(73) Assignee: LG ELECTRONICS INC., Seoul (KR)

(21) Appl. No.: 18/629,263

(22) Filed: Apr. 8, 2024

(30) Foreign Application Priority Data
Nov. 24, 2023 (KR) 10-2023-0165883

(51) Int. Cl. H01L 33/62; H01L 25/075; H01L 33/46; H01L 33/58

(52) U.S. Cl. CPC H10H 20/857; H01L 25/0753; H10H 20/841; H10H 20/855

(57) ABSTRACT

The present disclosure is applicable to display device-related technology, and for example, relates to a display device and a liquid crystal display device with improved image quality and reliability. The display device using a light emitting device includes a distribution board including a reflective layer, a pair of electrode pads partitioned in an area other than the reflective layer on the distribution board and constituting a plurality of unit pixels or subpixels, a light source including a light emitting device electrically connected to the pair of electrode pads and a lens covering the light emitting device, and a first light absorption pattern located outside the light emitting device within a width defined between the pair of electrode pads within the lens.

Pursuant to 35 U.S.C. § 119(a), this application claims the benefit of earlier filing date and right of priority to Korean Application No. 10-2023-0165883, filed on Nov. 24, 2023, the contents of which are hereby incorporated by reference herein in their entirety.

### TECHNICAL FIELD

The present disclosure is applicable to display device-related technology, and for example, relates to a display device and a liquid crystal display device with improved image quality and reliability.

### BACKGROUND

In general, among displays, liquid crystal display (LCD) devices are used in a variety of devices ranging from televisions, laptop computers, and desktop computer monitors to mobile phones.

The LCD is not capable of autonomously emitting light, and thus there is a need for a light emitting device for illuminating a liquid crystal panel to display image information.

The light emitting device of the LCD is coupled to a rear surface of a liquid crystal panel, and thus is referred to as a flat lighting device or a backlight unit, and the backlight unit may be a device that forms a uniform surface light source to provide the light source to the liquid crystal panel.

The backlight unit provides a flat light source to the liquid crystal panel, and thus may be seen as an example of a flat lighting device. Such a flat lighting device is recognized as a light source that may uniformly emit light through a flat surface and has a relatively small thickness.

A light emitting device such as a light emitting diode is used as a light source for the flat lighting device.

When the flat lighting device provides flat lighting, there may be a portion between light sources that appear darker than surroundings (dark area) or a portion between the light sources that appear lighter than the surroundings (light area).

When several display devices are combined to form a large display device, a phenomenon may occur in which a boundary between separate display devices appears darker or lighter than other portions and is visible.

Therefore, there is a need for a method to resolve these problems.

### SUMMARY

An object of the present disclosure is to provide a display device and a liquid crystal display device, which prohibit or prevent light and dark areas from being generated from a display device such as a flat lighting device.

Another object of the present disclosure is to provide a display device and a liquid crystal display device with improved reliability.

Another object of the present invention is to resolve various problems not mentioned here. Those skilled in the art may understand the entire objects of the specification and drawings.

To achieve the above objects, the present disclosure provides a display device using a light emitting device, including a distribution board including a reflective layer, a pair of electrode pads partitioned in an area other than the reflective layer on the distribution board and constituting a plurality of unit pixels or subpixels, a light source including a light emitting device electrically connected to the pair of electrode pads and a lens covering the light emitting device, and a first light absorption pattern located outside the light emitting device within a width defined between the pair of electrode pads within the lens

The first light absorption pattern may include a pad separator located between the pair of electrode pads

The pad separator may include an insulating layer that is opened and exposed at a location between the pair of electrode pads.

The insulating layer may have a lower-contrast color than the reflective layer including black.

The first light absorption pattern may be located symmetrically with respect to the light emitting device on both sides of the light emitting device.

The distribution board may include a substrate, and a black insulating layer located on the substrate, and the reflective layer may be formed by opening the black insulating layer to be exposed outside the light emitting device to form the first light absorption pattern.

The first light absorption pattern may include at least one of a dot pattern, a line pattern, and an arc pattern

The display device may further include a second light absorption pattern located outside a lens of the light source.

The second light absorption pattern may be located at a location extending within a width defined between the pair of electrode pads.

The second light absorption pattern may include at least one of a dot pattern, a line pattern, and a circular pattern.

To achieve the above objects, the present disclosure provides a display device including a distribution board including a reflective layer, a pair of electrode pads partitioned in an area other than the reflective layer on the distribution board, constituting a plurality of unit pixels or subpixels, and separated by a pad separator, a light source including a light emitting device electrically connected to the pair of electrode pads and a lens covering the light emitting device, and a first light absorption pattern located within a width defined by the pad separator inside the lens or located symmetrically on both sides of the light emitting device around the pad separator.

The pad separator may include a black insulating layer that is opened and exposed at a location between the pair of electrode pads.

The display device may further include a second light absorption pattern located at a location extending within a width defined between the pair of electrode pads.

According to an embodiment of the present disclosure, a phenomenon in which light and dark areas is generated or a boundary between the light and dark areas is visible may be prevented in a display device such as a flat lighting device.

Accordingly, image quality of a liquid crystal display device using a display device such as a flat lighting device may be improved.

Furthermore, according to another embodiment of the present disclosure, there are additional technical effects not mentioned herein. Those skilled in the art may understand the technical effects through the entire contents of the specification and drawings.

### BRIEF DESCRIPTION OF THE DRAWINGS

The present disclosure will become more fully understood from the detailed description given herein below and the accompanying drawings, which are given by illustration only, and thus are not limitative of the present disclosure.

FIG. 1 is a plan view of a display device using a light emitting device according to an embodiment of the present disclosure;

FIG. 2 is a plan view showing a state before a light emitting device of a display device using a light emitting device is mounted, according to an embodiment of the present disclosure;

FIG. 3 is a cross-sectional view of a portion of a display device using a light emitting device, on which a separate light source is located, according to an embodiment of the present disclosure;

FIGS. 4 to 6 are conceptual diagrams showing a first light absorption pattern of a display device using a light emitting device according to a first embodiment of the present disclosure;

FIG. 7 is a conceptual diagram showing a first light absorption pattern of a display device using a light emitting device according to a second embodiment of the present disclosure;

FIG. 8 is a conceptual diagram showing a first light absorption pattern of a display device using a light emitting device according to a third embodiment of the present disclosure;

FIG. 9 is a conceptual diagram showing a first light absorption pattern of a display device using a light emitting device according to the third embodiment of the present disclosure;

FIG. 10 is a plan view showing a state in which a light emitting device and a lens are installed in a first light absorption pattern of a display device using a light emitting device according to the second embodiment of the present disclosure;

FIG. 11 is a schematic diagram showing a light source of a display device using a light emitting device according to embodiments of the present disclosure;

FIGS. 12 to 14 are conceptual diagrams showing a second light absorption pattern of a display device using a light emitting device according to an embodiment of the present disclosure;

FIG. 15 is a plan view showing a display device using a light emitting device according to another embodiment of the present disclosure; and

FIG. 16 is an exploded diagram showing a liquid crystal display device including a display device according to an embodiment of the present disclosure.

### DETAILED DESCRIPTION

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions.

In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

A semiconductor light-emitting device mentioned herein is a concept including an LED, a micro LED, and the like, and is able to be used interchangeably with those.

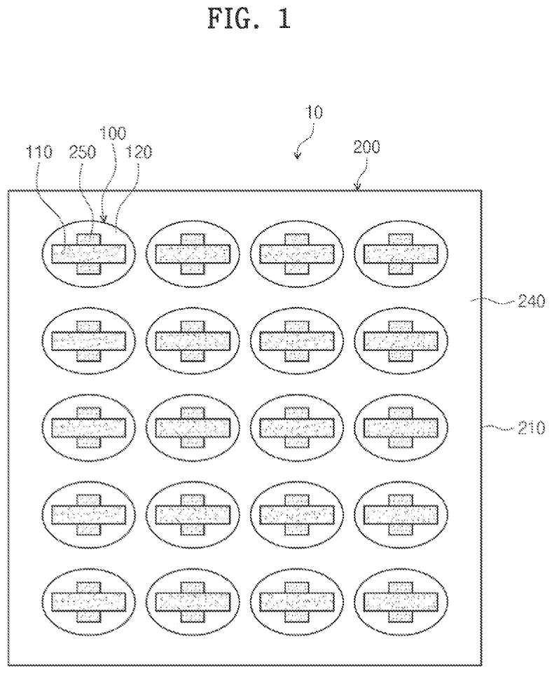

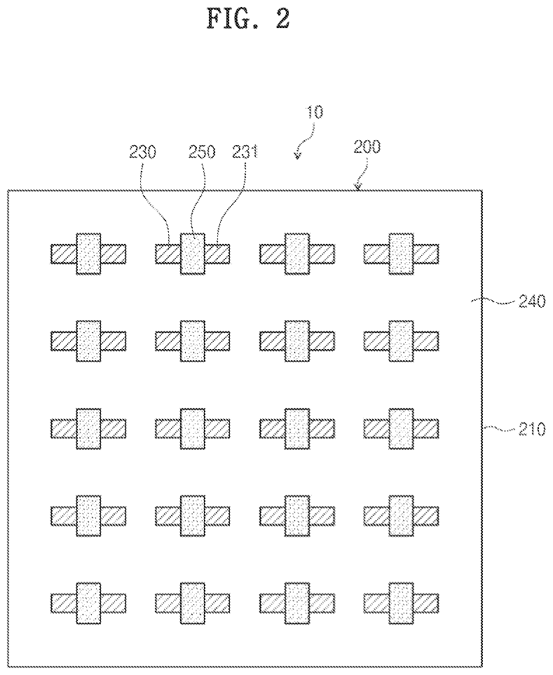

FIG. 1 is a plan view of a display device using a light emitting device according to an embodiment of the present disclosure. FIG. 2 is a plan view showing a state before a light emitting device of a display device using a light emitting device is mounted, according to an embodiment of the present disclosure.

Referring to FIGS. 1 and 2, a display device 10 may be configured by installing a plurality of unit light sources 100 that implement separate unit pixels or subpixels on a distribution board 200.

A pair of electrode pads 230 and 231 constituting a plurality of unit pixels or subpixels may be provided on the distribution board 200, and a light emitting device 110 constituting a light source 100 may be electrically connected to and mounted on the pair of electrode pads 230 and 231.

The light source 100 may include the light emitting device 110 electrically connected to the pair of electrode pads 230 and 231 and the lens 120 covering the light emitting device 110.

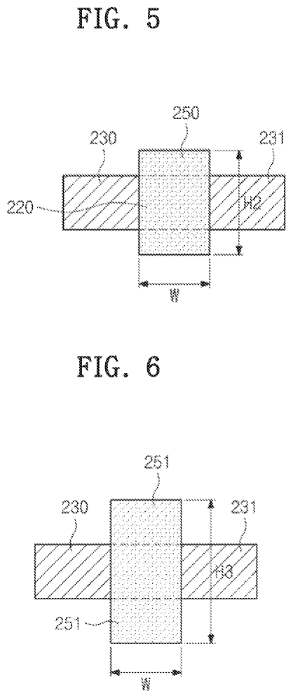

A first light absorption pattern 250 located outside the light emitting device 110 within a width W (refer to FIG. 5) defined as an interval between the pair of electrode pads 230 and 231 inside a lens 120 of the light source 100 may be provided between the pair of electrode pads 230 and 231.

According to an embodiment, the first light absorption pattern 250 may be connected to a pad separator 220 (refer to FIG. 4) that electrically separates the pair of electrode pads 230 and 231 from each other. For example, the first light absorption pattern 250 may mean an extension of the pad separator 220.

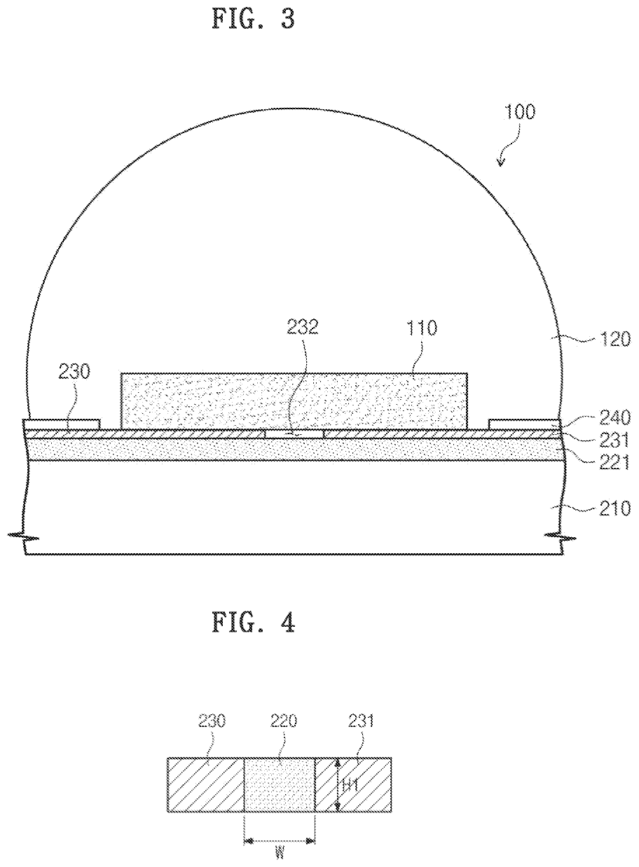

The first light absorption pattern 250 may be a portion of an insulating layer 221 (refer to FIG. 3) that is opened and exposed at a location between the pair of electrode pads 230 and 231. For example, the insulating layer 221 may be located inside a reflective layer 240, and the portion of the insulating layer 221, which is exposed by an opening 232 at a location between the pair of electrode pads 230 and 231, may correspond to the pad separator 220. A portion that is exposed outside the light emitting device 110 by expanding the pad separator 220 may correspond to the first light absorption pattern 250.

The insulating layer 221, the pad separator 220, and the first light absorption pattern 250 may have a low-contrast color including black. For example, the contrast of the insulating layer 221, the pad separator 220, and the first light absorption pattern 250 may be lower than that of the reflective layer 240.

According to an embodiment, the pad separator 220 or the first light absorption pattern 250 may be located symmetrically with respect to the light emitting device 110 on both sides of the light emitting device 110. The pad separator 220 or the first light absorption pattern 250 may be located inside the lens 120.

For example, the pad separator 220 may be the same as a width of the light emitting device 110, but as shown in FIGS. 1 and 2, the pad separator 220 may be expanded larger than the width of the light emitting device 110 and exposed outside the light emitting device 110 to act as the first light absorption pattern 250 in a state in which the light emitting device 110 is mounted on the pair of electrode pads 230 and 231.

As such, the first light absorption pattern 250 may be located outside the light emitting device 110 within the width W (refer to FIG. 5) defined between the pair of electrode pads 230 and 231 inside the lens 120 of the light source 100, thereby preventing light and dark areas from being generated in the display device 10.

According to an embodiment, a liquid crystal panel (not shown) may be located on the display device 10. For example, the display device 10 may correspond to a backlight unit or a flat lighting device that provides uniform white light. Hereinafter, the display device 10 according to an embodiment of the present disclosure will be described as a flat lighting device 10 as an example. However, the present disclosure is not limited thereto. Hereinafter, the display device 10 and the flat lighting device 10 will be described using the same reference numerals. In the case of the flat lighting device 10, the light emitting device 110 of the light source 100 may be the light emitting device 110 that emits white light.

When the display device 10 provides flat lighting, a portion between the light sources 100 that appear darker than surroundings (dark area) or a portion between the light sources that appear lighter than the surroundings (light area). When several display devices 10 are combined to form a large display device 10, a phenomenon may occur in which a boundary between separate display devices 10 appears darker or lighter than other portions and is visible.

However, according to an embodiment of the present disclosure, it may be possible to prevent the light and dark areas from being generated or a boundary from being visible by an action of the first light absorption pattern 250. This will be described below in detail.

FIG. 3 is a cross-sectional view of a portion of a display device using a light emitting device, on which a separate light source is located, according to an embodiment of the present disclosure. FIGS. 4 to 6 are conceptual diagrams showing a first light absorption pattern of a display device using a light emitting device according to a first embodiment of the present disclosure.

Referring to FIG. 3, the drawing shows a cross section of a unit light source 100 of the display device 10. As described above, the light source 100 may be provided on the distribution board 200.

In the distribution board 200, the insulating layer 221 may be located on a (base) substrate 210. The pair of electrode pads 230 and 231 constituting a unit pixel or a subpixel may be provided on the insulating layer 221, and the light emitting device 110 constituting the light source 100 may be electrically connected and mounted on the pair of electrode pads 230 and 231.

In this case, although not shown separately, for example, a distribution electrode (common electrode or scan electrode) connected to the pair of electrode pads 230 and 231 may be located between the substrate 210 and the insulating layer 221.

As another example, the electrode pads 230 and 231 may be connected to a distribution electrode (common electrode or scan electrode) on the insulating layer 221. For example, portions excluding the electrode pads 230 and 231 may be covered by the reflective layer 240 to function as a distribution electrode or be connected to the distribution electrode.

The pair of electrode pads 230 and 231 may be separated by the opening 232. Due to the opening 232, the insulating layer 221 may be exposed at a location between the electrode pads 230 and 231. As such, a portion of the insulating layer 221 may be exposed by the opening 232 to form the pad separator 220 or the first light absorption pattern 250.

As described above, the insulating layer 221, the pad separator 220, and the first light absorption pattern 250 may have a low-contrast color including black. For example, the contrast of the insulating layer 221, the pad separator 220, and the first light absorption pattern 250 may be lower than that of the reflective layer 240.

The light emitting device 110 may be mounted on the pair of electrode pads 230 and 231. The lens 120 may be located on the light emitting device 110. Accordingly, portions excluding the light emitting device 110 and the pad separator 220 may be covered by the reflective layer 240.

Referring to FIG. 4, the drawing shows the pair of electrode pads 230 and 231 and the pad separator 220 located therebetween before the light emitting device 110 is mounted.

The light emitting device 110 may have substantially the same width H1 as the pair of electrode pads 230 and 231. The light emitting device 110 may be installed to cover the pair of electrode pads 230 and 231 and the pad separator 220, and thus the height H1 of the pair of electrode pads 230 and 231 may be actually the width H1 of the light emitting device 110. That is, the height H1 of the electrode pads 230 and 231 may be equal to the width H1 of the light emitting device 110.

In this case, the pad separator 220 located between the pair of electrode pads 230 and 231 has a certain width W. As in the case of FIG. 4, when the height H1 of the pad separator 220 is the same as the height H1 of the electrode pads 230 and 231, if the light emitting device 110 is mounted, the pad separator 220 is covered by the light emitting device 110.

However, in the case of the first light absorption pattern 250 having a height H2 greater than the height H1 of the electrode pads 230 and 231, as in the case of FIG. 5, or a first light absorption pattern 251 having a height H3 greater than the height H1 of the electrode pads 230 and 231, when the light emitting device 110 is mounted, a portion of the first light absorption pattern 250 or the first light absorption pattern 251, excluding a portion corresponding to the width H1 of the light emitting device 110, may be exposed. In this case, when the light emitting device 110 is mounted, the first light absorption patterns 250 and 251 may be exposed outside the width H1 of the light emitting device 110.

The first light absorption patterns 250 and 251 may be located outside the light emitting device 110 within the width W (refer to FIG. 5) defined between the pair of electrode pads 230 and 231 inside the lens 120 of the light source 100, thereby preventing light and dark areas from being generated in the display device 10.

For example, as in the case of FIG. 4, when only the pad separator 220 is located between the electrode pads 230 and 231, the pad separator 220 may be covered by the light emitting device 110, and when the display device 10 is implemented, a light area may be generated around the light source 100.

As in the case of FIGS. 5 and 6, when the first light absorption patterns 250 and 251 are provided, the first light absorption patterns 250 and 251 may not be covered by the light emitting device 110, and a light area may be prevented from being generated around the light source 100.

However, when the height of the first light absorption patterns 250 and 251 increases, a dark area may be generated around the light source 100. Therefore, the height of the first light absorption patterns 250 and 251 may be adjusted to a certain height to prevent light and dark areas from being generated around the light source 100.

According to an embodiment, the width W and the height H2 or H3 of the first light absorption patterns 250 and 251 may be adjusted to prevent light and dark lines from being generated around the light source 100.

The width W of the first light absorption patterns 250 and 251 may be fixed depending on implementation of the display device 10. Thus, the height H2 or H3 of the first light absorption patterns 250 and 251 may be adjusted. Here, the height H2 or H3 of the first light absorption patterns 250 and 251 may be a value including the height H1 of the pad separator 220.

In a state in which the width W of the first light absorption patterns 250 and 251 is fixed, effects according to the height H2 or H3 of the first light absorption patterns 250 and 251 are summarized in Table 1 below.

TABLE 1

| Width of first light | Height of first light | |
|---|---|---|
| absorption pattern | absorption pattern | Effect |
| 0.13 mm | 0.25 mm | Strong light line |
| 0.13 mm | 0.3 mm | Weak light line |
| 0.13 mm | 0.4 mm | Weak light line |
| 0.13 mm | 0.5 mm | Strong dark line |

As seen from Table 1, according to an embodiment, when the height H2 or H3 of the first light absorption patterns 250 and 251 is between about 2.3 mm and about 3.0 mm with respect to the width W, light and dark lines may be prevented from being generated.

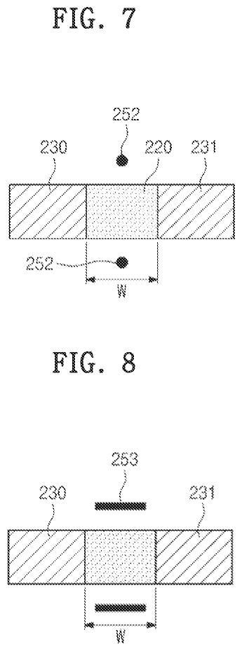

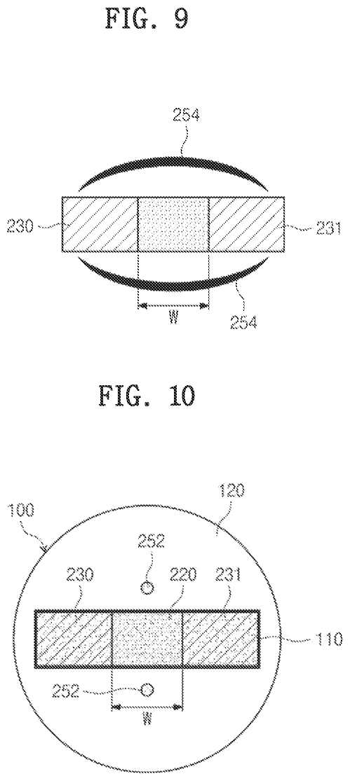

FIG. 7 is a conceptual diagram showing a first light absorption pattern of a display device using a light emitting device according to a second embodiment of the present disclosure. FIG. 8 is a conceptual diagram showing a first light absorption pattern of a display device using a light emitting device according to a third embodiment of the present disclosure. FIG. 9 is a conceptual diagram showing a first light absorption pattern of a display device using a light emitting device according to the third embodiment of the present disclosure. FIG. 10 is a plan view showing a state in which a light emitting device and a lens are installed in a first light absorption pattern of a display device using a light emitting device according to the second embodiment of the present disclosure.

Referring to FIG. 7, the drawing shows a first light absorption pattern 252 according to the second embodiment. The first light absorption pattern 252 according to the second embodiment may have a shape of a dot pattern.

As in the case of the first embodiment described above, the first light absorption pattern 252 may not be covered by the light emitting device 110 even when the light emitting device 110 is mounted, and may be located on both sides of the light emitting device 110, thereby preventing a light area or a dark area from being generated around the light source 100.

The first light absorption patterns 252 may be located outside the width H1 of the light emitting device 110. Simultaneously, the first light absorption patterns 252 may be located within the width W of the pad separator 220. For example, the first light absorption patterns 252 may be apart on both sides of the light emitting device 110 within the width W of the pad separator 220. However, the first light absorption pattern 252 may be located inside the lens 120 as shown in FIG. 10.

Referring to FIG. 8, the drawing shows a first light absorption pattern 253 according to the third embodiment. The first light absorption pattern 253 according to the third embodiment may have a pattern of a bar shape.

Like the second embodiment, the first light absorption patterns 253 may be located outside the width H1 of the light emitting device 110. Simultaneously, the first light absorption patterns 253 may be located within the width W of the pad separator 220. For example, the first light absorption patterns 253 may be apart on both sides of the light emitting device 110 within the width W of the pad separator 220. However, the first light absorption patterns 253 may be located inside the lens 120.

Referring to FIG. 9, the drawing shows a first light absorption pattern 254 according to a fourth embodiment. The first light absorption pattern 254 according to this fourth embodiment may have an arc shape with a certain curvature. The arc shape may be provided to surround the light emitting device 110 symmetrically with respect to the position of the light emitting device 110. The center of the first light absorption pattern 254 according to the fourth embodiment may coincide with the center of the pad separator 220.

As such, the first light absorption patterns 254 may be located outside the width H1 of the light emitting device 110. Simultaneously, a central location of the first light absorption patterns 254 may correspond to a central location of the width W of the pad separator 220. For example, the first light absorption patterns 254 may be apart on both sides of the light emitting device 110 within the width W of the pad separator 220. However, the first light absorption patterns 254 may be located inside the lens 120.

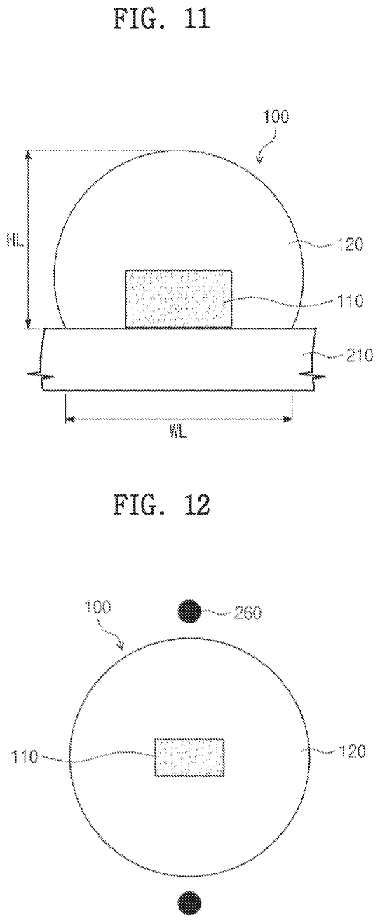

FIG. 11 is a schematic diagram showing a light source of a display device using a light emitting device according to embodiments of the present disclosure.

Referring to FIG. 11, the light emitting device 110 constituting the light source 100 may be covered by the lens 120. In this case, the lens 120 may have a width WL and a height HL. Due to a shape of the lens 120, a light area or a dark area may be prevented from being generated around the light source 100. The shape of the lens 120 and the first light absorption patterns 250, 251, 252, 253, and 254 may be combined to prevent a light area or a dark area from being generated around the light source 100.

Table 2 shows an effect of adjusting the width WL and the height HL of the lens 120 in a state in which the first light absorption pattern 250 having the height H2 greater than the height H1 of the electrode pads 230 and 231 is used, as in the case of FIG. 5.

TABLE 2

| Embodiment 1 | | Width | | Height | | Rate | Effect |
|---|---|---|---|---|---|---|---|
| 0.13 | mm | 4 | mm | 1.15 | mm | 28.8% | Light line |
| 0.3 | mm | 4.2 | mm | 1.1 | mm | 26.2% | Weak light line |
| | | 4.4 | mm | 1.07 | mm | 24.3% | Weaker light line |
| | | 4.6 | mm | 1 | mm | 21.7% | Dark line visible |

As seen from Table 2, when a rate of the width WL and the height HL of the lens 120 is adjusted between about 21.7% and about 26.2%, light and dark lines may be prevented from being generated around the light source 100. It may be seen that, when a rate of the width WL and the height HL of the lens 120 is adjusted along with the first light absorption pattern 251, for example, when a rate of the width WL and the height HL is 24.3%, the light line is further prevented.

Table 3 shows an effect of adjusting the width WL and the height HL of the lens 120 in a state in which the first light absorption pattern 251 having the height H3 greater than the height H1 of the electrode pads 230 and 231 is used, as in the case of FIG. 6.

TABLE 3

| Embodiment 2 | | Width | | Height | | Rate | Effect |
|---|---|---|---|---|---|---|---|
| 0.13 | mm | 4 | mm | 1.15 | mm | 28.8% | Light line |
| 0.4 | mm | 4.2 | mm | 1.1 | mm | 26.2% | Weak dark line |
| | | 4.4 | mm | 1.07 | mm | 24.3% | Dark line |
| | | 4.6 | mm | 1 | mm | 21.7% | Dark line |

As seen from Table 3, when a rate of the width WL and the height HL of the lens 120 is adjusted along with the first light absorption pattern 251, for example, when a rate of the width WL and the height HL is 26.2%, the light line may be prevented.

Table 4 shows an effect of adjusting the width WL and the height HL of the lens 120 in a state in which the first light absorption pattern 252 having a dot shape is used.

TABLE 4

| | Width | | Height | | Rate | Effect |
|---|---|---|---|---|---|---|
| First light | 4 | mm | 1.15 | mm | 28.8% | Light line |
| absorption | 4.2 | mm | 1.1 | mm | 26.2% | Weak light line |
| pattern (dot) | 4.4 | mm | 1.07 | mm | 24.3% | Much weaker light line |
| | 4.6 | mm | 1 | mm | 21.7% | Dark line visible |

As seen from Table 4, when a rate of the width WL and the height HL of the lens 120 is adjusted between about 21.7% and about 26.2%, an effect of preventing light and dark lines from being generated around the light source 100. It may be seen that this case may coincide with the case in which the first light absorption pattern 251 according to the first embodiment is used.

It may be seen that, when a rate of the width WL and the height HL of the lens 120 is adjusted along with the first light absorption pattern 252, for example, when a rate of the width WL and the height HL is 24.3%, a light line may be further prevented.

FIGS. 12 to 14 are conceptual diagrams showing a second light absorption pattern of a display device using a light emitting device according to an embodiment of the present disclosure.

Referring to FIG. 12, the display device 10 may further include a second light absorption pattern 260 around the light source 100. For example, the second light absorption pattern 260 may be located outside the lens 120 of the light emitting device 110.

The second light absorption pattern 260 may be located at a location extending within the width W defined between the pair of electrode pads 230 and 231. For example, the second light absorption pattern 260 may be located extending from a location corresponding to the center of the pad separator 220.

The second light absorption pattern 260 according to an embodiment may have a pattern of a dot shape. For example, the second light absorption pattern 260 may be located at a certain distance away from a longitudinal side of the light emitting device 110 to the outside of the lens 120.

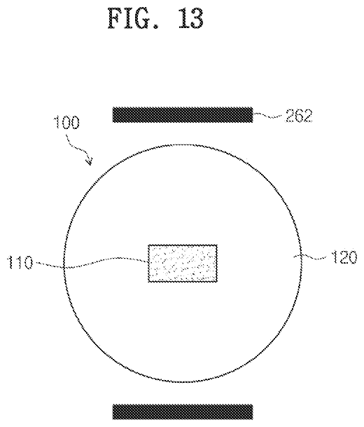

As shown in FIG. 13, a second light absorption pattern 261 having a bar shape may be provided. For example, a length of the second light absorption pattern 261 having a bar shape may be greater than the length of the first light absorption pattern 253 having the bar shape described above.

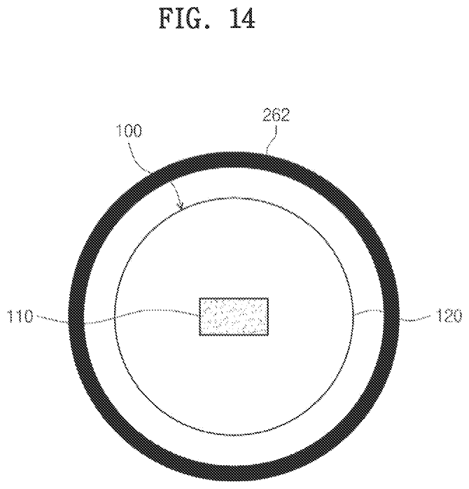

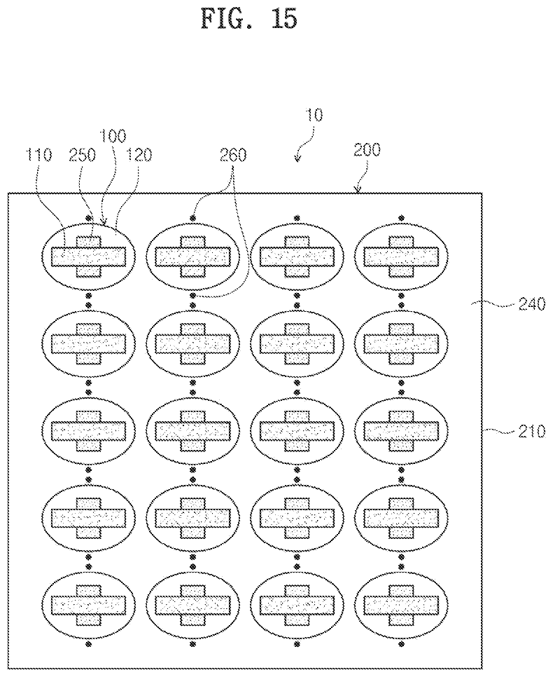

As shown in FIG. 14, a second light absorption pattern 262 having a circular shape may be provided. In this case, the second light absorption pattern 262 having a circular shape may be located concentrically with the lens 120.

FIG. 15 is a plan view showing a display device using a light emitting device according to another embodiment of the present disclosure.

Referring to FIG. 15, the drawing shows an example of the display device 10 to which the second light absorption pattern 260 is applied. As described above, the second light absorption pattern 260 may be used with the first light absorption patterns 250 to 254 described above. The second light absorption pattern 260 may be used along with adjustment of the ratio of the width WL and the height HL of the lens 120.

Table 5 shows an effect of adjusting a rate of the width WL and the height HL of the lens 120 when the first light absorption pattern 250 and the second light absorption pattern 260 are used together.

TABLE 5

| | Width | | Height | | Rate | Effect |
|---|---|---|---|---|---|---|
| Add second | 4 | mm | 1.15 | mm | 28.8% | Light line |
| light | 4.2 | mm | 1.1 | mm | 26.2% | Weak light line |
| absorption | 4.4 | mm | 1.07 | mm | 24.3% | Almost invisible line |
| pattern | 4.6 | mm | 1 | mm | 21.7% | Dark line visible |

As seen from Table 5, when a rate of the width WL and the height HL of the lens 120 is adjusted between about 21.7% and about 26.2%, an effect of preventing light and dark lines from being generated around the light source 100 may be obtained. When a rate of the width WL and the height HL of the lens 120 is 24.3%, the prevention effect may be further improved. It may be seen that these results are consistent with the examples described above.

As described above, at least one or more of ratio adjustments of the width WL and the height HL of the first light absorption patterns 250 to 254, the second light absorption patterns 260 to 262, and the lens 120 may be combined and used

When the display device 10 provides flat lighting by using at least one or more of ratio adjustments of the width WL and the height HL of the first light absorption patterns 250 to 254, the second light absorption patterns 260 to 262, and the lens 120, a phenomenon of generating a portion between light sources that appear darker than surroundings (dark area) or a portion between the light sources that appear lighter than the surroundings (light area) may be prevented or prohibited. Thus, image quality of the display device 10 or the flat lighting device 10 may be improved.

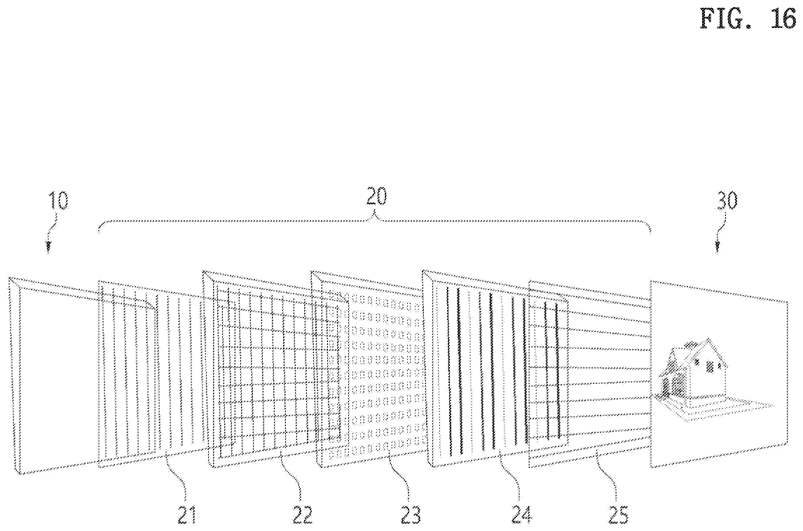

FIG. 16 is an exploded diagram showing a liquid crystal display device including a display device according to an embodiment of the present disclosure.

Hereinafter, an example in which the display device 10 is the flat lighting device 10 will be described.

Referring to FIG. 16, a liquid crystal display panel 20 may be located on the flat lighting device 10. The flat lighting device 10 and the liquid crystal display panel 20 may be combined to constitute a liquid crystal display device 30.

As described above, the flat lighting device 10 may include the plurality of light sources 100 that emit white light.

As described above, the flat lighting device 10 may include combined characteristics of at least one or more of ratio adjustments of the width WL and the height HL of the first light absorption patterns 250 to 254, the second light absorption patterns 260 to 262, and the lens 120.

The liquid crystal display panel 20 may be located on the flat lighting device 10.

Referring to FIG. 16, the liquid crystal display panel 20 may include a first polarizer 21, a thin film transistor (TFT) 22, a liquid crystal cell 23, a color filter 24, and a second polarizer 25.

The liquid crystal display panel 20 may implement display by using unit pixels of a display device defined by the liquid crystal cell 23. The liquid crystal display panel 20 may include the TFT 22 for driving of an active matrix (AM).

The color filter 24 may implement red, green, and blue light applied to a unit pixel by using white light emitted from the flat lighting device 10.

Therefore, the liquid crystal display panel 20 may implement a full color display using light emitted from the flat lighting device 10. In other words, the flat lighting device 10 may implement a liquid crystal display device together with the liquid crystal display panel 20. Hereinafter, a detailed description of the liquid crystal display panel 20 will be omitted.

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are not intended to limit the technical idea of the present disclosure, but to describe, and the scope of the technical idea of the present disclosure is not limited by such embodiments.

The scope of protection of the present disclosure should be interpreted by the claims below, and all technical ideas within the scope equivalent thereto should be construed as being included in the scope of the present disclosure.

What is claimed is:

1. A display device using a light emitting device, the display device comprising:
a distribution board including a reflective layer;
a pair of electrode pads partitioned in an area other than the reflective layer on the distribution board and constituting a plurality of unit pixels or subpixels;
a light source including a light emitting device electrically connected to the pair of electrode pads and a lens covering the light emitting device; and
a first light absorption pattern located outside the light emitting device within a width defined between the pair of electrode pads within the lens.

2. The display device of claim 1, wherein the first light absorption pattern includes a pad separator located between the pair of electrode pads.

3. The display device of claim 2, wherein the pad separator includes an insulating layer that is opened and exposed at a location between the pair of electrode pads.

4. The display device of claim 3, wherein the insulating layer has a lower-contrast color than the reflective layer including black.

5. The display device of claim 1, wherein the first light absorption patterns are located symmetrically with respect to the light emitting device on both sides of the light emitting device.

6. The display device of claim 1, wherein the distribution board includes:
a substrate; and
a black insulating layer located on the substrate, and
the reflective layer is formed by opening the black insulating layer to be exposed outside the light emitting device to form the first light absorption pattern.

7. The display device of claim 1, wherein the first light absorption pattern includes at least one of a dot pattern, a line pattern, and an arc pattern.

8. The display device of claim 1, further comprising a second light absorption pattern located outside a lens of the light source.

9. The display device of claim 8, wherein the second light absorption pattern is located at a location extending within a width defined between the pair of electrode pads.

10. The display device of claim 8, wherein the second light absorption pattern includes at least one of a dot pattern, a line pattern, and a circular pattern.

11. A display device comprising:
a distribution board including a reflective layer;
a pair of electrode pads partitioned in an area other than the reflective layer on the distribution board, constituting a plurality of unit pixels or subpixels, and separated by a pad separator;
a light source including a light emitting device electrically connected to the pair of electrode pads and a lens covering the light emitting device; and
a first light absorption pattern located within a width defined by the pad separator inside the lens or located symmetrically on both sides of the light emitting device around the pad separator.

12. The display device of claim 11, wherein the pad separator includes a black insulating layer that is opened and exposed at a location between the pair of electrode pads.

13. The display device of claim 11, wherein the distribution board includes:
a substrate; and
a black insulating layer located on the substrate, and
the reflective layer is formed by opening the black insulating layer to be exposed outside the light emitting device to form the first light absorption pattern.

14. The display device of claim 11, wherein the first light absorption pattern includes at least one of a dot pattern, a line pattern, and an arc pattern.

15. The display device of claim 12, further comprising a second light absorption pattern located at a location extending within a width defined between the pair of electrode pads.
